(19) United States
(12) Patent Application Publication
(10) Pub. No.: US 2007/0005863 A1
(43) Pub. Date: Jan. 4, 2007

(54) HOT-PLUGGABLE VIDEO DISPLAY CARD AND COMPUTER SYSTEM THEREOF

(75) Inventors: An-Sheng Chang, Taipei Hsien (TW); Po-Hao Pan, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: GIGA-BYTE TECHNOLOGY CO.,LTD., Taipei Hsien (TW)

(21) Appl. No.: 11/531,685

(22) Filed: Sep. 13, 2006

(30) Foreign Application Priority Data
Jun. 28, 2006 (TW) 95123293

(51) Int. Cl. G06F 13/00; H05K 7/10

(52) U.S. Cl. 710/302

(57) ABSTRACT

A hot-pluggable video display card and a computer system thereof are provided. The video display card includes a hot-pluggable host-side interface, a video processing unit, and a display-device-side interface. The hot-pluggable host-side interface provides the interface with “hot plug-n-play” function between the video display card and a host unit. The display-device-side interface provides the interface between the video display card and a display device. The video processing unit is coupled between the hot-pluggable host-side interface and the display-device-side interface. The video processing unit receives the video data output by the host unit and carries out video processing. Thereby, the video display card can process the video data output by the host unit and transmit the video processing result of the video processing unit to the display device.

### CROSS-REFERENCE TO RELATED APPLICATION

This application claims the priority benefit of Taiwan application serial no. 95123293, filed Jun. 28, 2006. All disclosure of the Taiwan application is incorporated herein by reference.

### BACKGROUND OF THE INVENTION

1. Field of the Invention

The present invention relates to a computer system and a video display card thereof. More particularly, the present invention relates to a hot-pluggable video display card and a computer system thereof.

2. Description of Related Art

Nowadays, a display card of a computer system mostly belongs to built-in type, that is, the display card has been embedded on the motherboard of the computer. The embedded display chip usually can only provide “standard display function”. Generally, such embedded display chip cannot meet the requirement of 3D or higher level video processing. The embedded display chip cannot be replaced, thus the user has to plug a display card of higher level into the extension slot of the computer system. The aforementioned extension slot is a video card connection port, for example, accelerated graphics port (“AGP” hereinafter). In the conventional computer system, none of the extension slots for plugging the display card can provide hot plug-n-play function. In other words, the user can only open up the case and disassemble the display card after the computer system is turned off.

As to a portable computer, for example, notebook computer, the display chip which can only provide “standard display function” has been embedded on the motherboard. To reduce the volume of the portable computer, most extension functions have been skipped, that is, there is no space or extension slot (such as AGP) preserved for plugging another display card in a portable computer. Accordingly, a portable computer can only fulfill video data processing of lower level (for example, word processing). Portable computers cannot meet existing and future requirements to 3D or higher level video processing.

### SUMMARY OF THE INVENTION

Accordingly, the present invention is directed to provide a hot-pluggable video display card to improve the display performance of a computer system. For example, the hot-pluggable video display card in the present invention can be assembled to a notebook computer to improve the processing performance of the notebook computer to 3D video.

According to another aspect of the present invention, a computer system is provided and a hot-pluggable video display card can be plugged to or unplugged from the computer system anytime through a hot-pluggable host-side interface without turning off the computer system. According to the present invention, the video processing performance of the computer system can be improved anytime without affecting the operation thereof.

Based on the aforementioned and other objectives, the present invention provides a hot-pluggable video display card for processing video data of a host unit and transmitting the processing result to a display device. The hot-pluggable video display card includes a hot-pluggable host-side interface, a video processing unit, and a display-device-side interface. The hot-pluggable host-side interface provides a connection interface between the hot-pluggable video display card and the host unit, wherein hot-pluggable host-side interface can provide hot plug-n-play function. The video processing unit is coupled to the hot-pluggable host-side interface. The video processing unit receives the video data output by the host unit and carries out video processing. The display-device-side interface is coupled to the video processing unit. The display-device-side interface provides a connection interface between the hot-pluggable video display card and the display device so that the hot-pluggable video display card can transmit the video processing result of the video processing unit to the display device.

According to another aspect of the present invention, a computer system is provided. The computer system includes a host unit, a hot-pluggable video display card, and a display device. The host unit includes a hot-pluggable slot which provides hot plug-n-play function. The aforementioned hot-pluggable video display card includes a hot-pluggable host-side interface, a video processing unit, and a display-device-side interface. The hot-pluggable host-side interface is coupled to the hot-pluggable slot for providing a connection interface between the hot-pluggable video display card and the host unit, wherein the hot-pluggable host-side interface can provides host plug-n-play function. The video processing unit is coupled to the hot-pluggable host-side interface. The video processing unit receives the video data output by the host unit and carries out video processing. The display-device-side interface is coupled to the video processing unit. The display device is coupled to the display-device-side interface of the hot-pluggable video display card. Wherein the hot-pluggable video display card transmits the video processing result of the video processing unit to the display device.

According to an exemplary embodiment of the present invention, the host unit further includes a chipset, and the hot-pluggable host-side interface is electrically connected to the chipset. Wherein, the hot-pluggable host-side interface can be electrically connected to the chipset through peripheral component interconnection express (referred to as “PCI Express” hereinafter) bus or other bus.

According to an exemplary embodiment of the present invention, the hot-pluggable host-side interface is up to the standard of PC card (or referred to as CMCIA card) or ExpressCard specified by Personal Computer Memory Card International Association (PCMCIA).

According to an exemplary embodiment of the present invention, the display-device-side interface may include the following interfaces: digital visual interface (referred to as “DVI” hereinafter), video graphics array (referred to as “VGA” hereinafter) interface (or referred to as “D-Sub interface”), separate video (referred to as “S-Video” hereinafter) interface, composite video interface (or referred to as “RCA interface”), universal serial bus (referred to as “USB” hereinafter) interface, etc.

According to an exemplary embodiment of the present invention, the host unit includes a portable computer. The USB interface of the hot-pluggable video display card is electrically connected to the USB interface of the portable computer so that the display device of the portable computer displays the video processing result output by the hot-pluggable video display card through the USB interface.

According to the present invention, a hot-pluggable video display card is connected to a host unit through a hot-pluggable host-side interface so that the hot-pluggable video display card can be plugged to or unplugged from the computer system anytime without turning off the computer system. In other words, the video processing performance of the computer system can be improved anytime without affecting the operation of the system. For example, the hot-pluggable video display card of the present invention can be directly connected to a notebook computer without turning off the notebook computer so that the 3D processing performance of the notebook computer can be improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a computer system according to an embodiment of the present invention.

FIG. 2 illustrates the appearance of PC card standard specified by PCMCIA.

FIG. 3A illustrates the appearance of ExpressCard standard of 54 mm width specified by PCMCIA.

FIG. 3B illustrates the appearance of ExpressCard standard of 34 mm width specified by PCMCIA.

FIG. 4A illustrates the display-device-side interface in the hot-pluggable video display card in FIG. 1 according to an embodiment of the present invention.

FIG. 4B illustrates the hot-pluggable video display card in FIG. 4A according to an embodiment of the present invention.

FIG. 5 illustrates the implementation of a hot-pluggable video display card according to an embodiment of the present invention.

### DESCRIPTION OF EMBODIMENTS

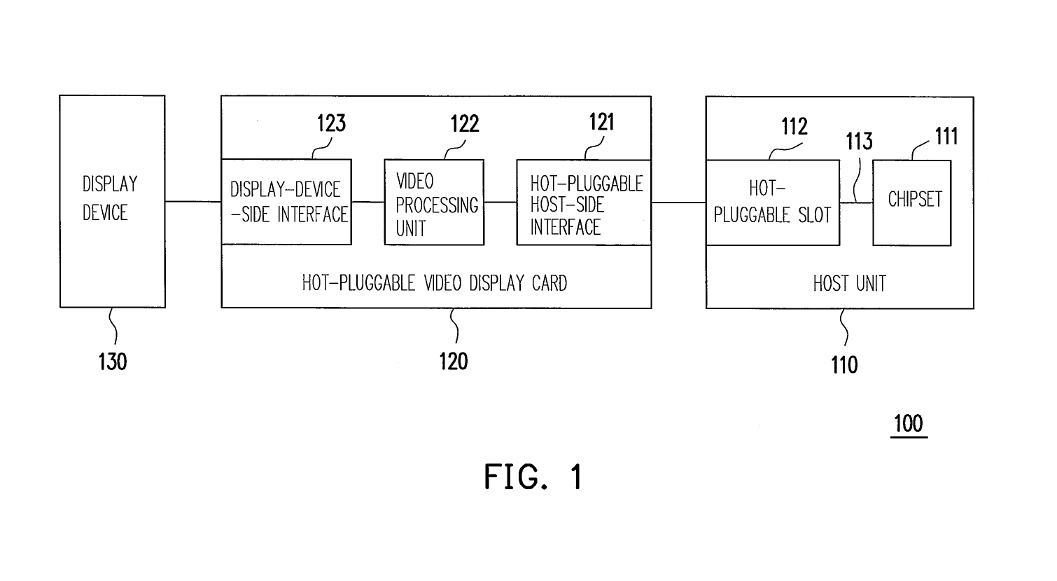

FIG. 1 is a block diagram of a computer system according to an embodiment of the present invention. Referring to FIG. 1, the computer system 100 includes a host unit 110, a hot-pluggable video display card 120, and a display device 130. The host unit 110 includes a hot-pluggable slot 112 and a chipset 111. The hot-pluggable video display card 120 includes a hot-pluggable host-side interface 121, a video processing unit 122, and a display-device-side interface 123. The hot-pluggable host-side interface 121 is coupled to the hot-pluggable slot 112 and is electrically connected to the chipset 111 through the hot-pluggable slot 112. The hot-pluggable host-side interface 121 provides a connection interface between the hot-pluggable video display card 120 and the host unit 110. The hot-pluggable slot 112 and the hot-pluggable host-side interface 121 can provide hot plug-n-play function. The video processing unit 122 is coupled between the hot-pluggable host-side interface 121 and the display-device-side interface 123. The video processing unit 122 receives the video data output by the host unit 110 and carries out video processing. The display device 130 is coupled to the display-device-side interface 123 of the hot-pluggable video display card. Wherein, the hot-pluggable video display card 120 transmits the video processing result of the video processing unit 122 to the display device 130.

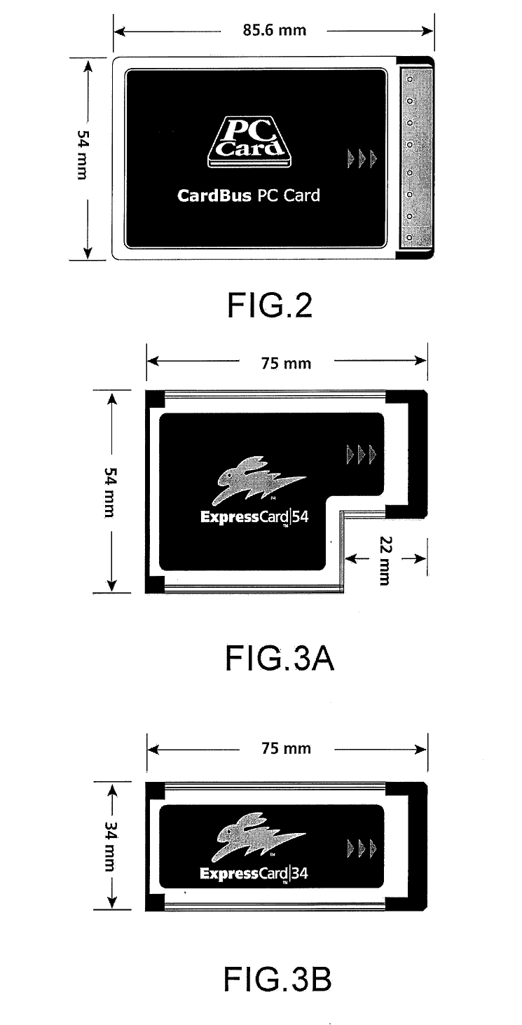

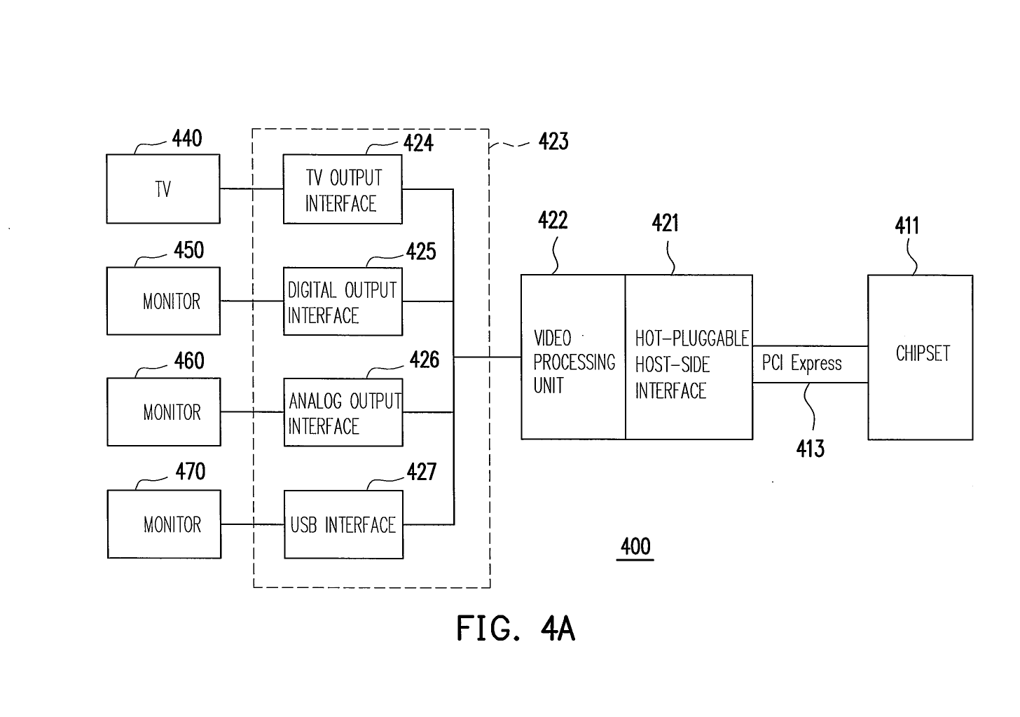

The hot-pluggable host-side interface 121 can be implemented according to the requirements by those having ordinary knowledge in the art, for example, the PC card standard as shown in FIG. 2 is an interface standard which provides hot plug-n-play function. In the present embodiment, ExpressCard standard will be used for implementing the hot-pluggable host-side interface, and PCI Express bus is used for implementing the bus 113 between the hot-pluggable host-side interface 121 (including the hot-pluggable slot 112) and the chipset 111. FIG. 3A and FIG. 3B respectively illustrate the appearance of ExpressCard standard of 54 mm and 34 mm width specified by PCMCIA. Please refer to related standards issued by PCMCIA for the specification of ExpressCard, for example, the website http://www.expresscard.org/web/site/.

A portable computer will be used as an example to clearly describe the implementation of the present invention. Those having ordinary knowledge in the art should be able to apply the present invention to other type of computer systems based on the spirit of the present invention and the following description of embodiments.

Regarding the portable computer (for example, a notebook computer), the display chip embedded in the mother board of the portable computer can only provide “standard display function”. Usually, the embedded display chip cannot meet the requirement of 3D or higher level video processing. Besides, most extension functions have to be skipped by portable computer to reduce the volume of the computer. That is, there is no space or extension slot (for example, AGP) preserved for inserting another video display card in a portable computer. Thus, the portable computer can only fulfill lower level video processing, for example, word processing. Regarding 3D or higher level video processing, the embedded display chip cannot be replaced, thus, the video processing performance of a portable computer cannot be improved by conventional technology.

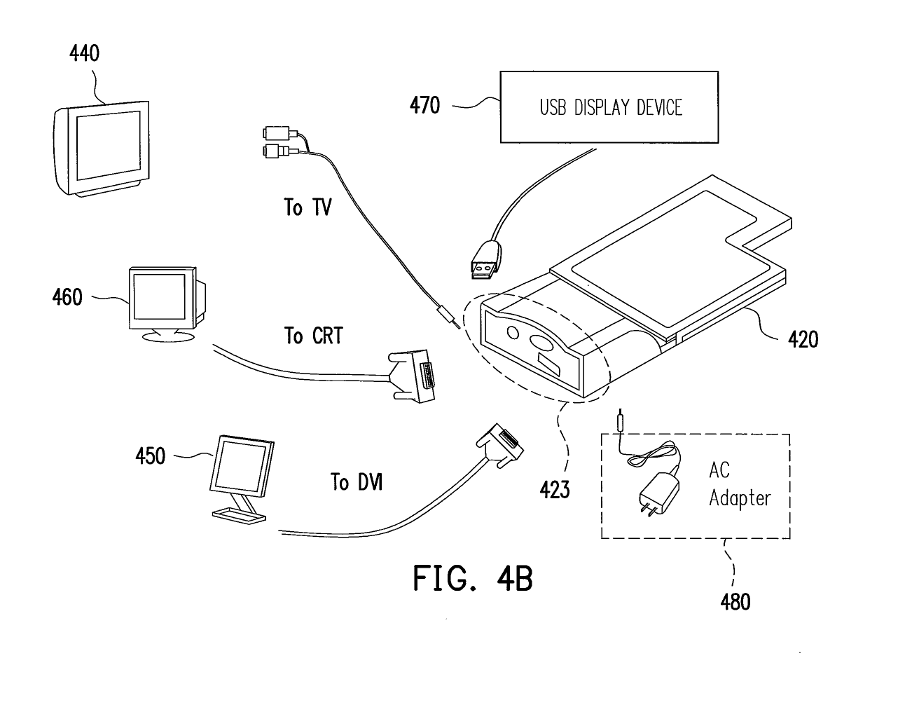

FIG. 4A illustrates the display-device-side interface in the hot-pluggable video display card in FIG. 1 according to an embodiment of the present invention. Referring to FIG. 4A, the portable computer 400 includes a chipset 411 and a PCI Express bus 413. The hot-pluggable video display card 420 includes a hot-pluggable host-side interface 421, a video processing unit 422, and a display-device-side interface 423. In the present embodiment, the hot-pluggable host-side interface 421 and the video processing unit 422 of the hot-pluggable video display card 420 are connected to the chipset 411 of the portable computer 400 through the PCI Express bus 413. Thus, the video data is transmitted to the video processing unit 422 through the PCI Express bus 413. The video processing unit 422 receives the video data output by the chipset 411 and carries out video processing. Wherein, the video processing carried out by the video processing unit 422 includes, for example, 3D video processing.

In the present embodiment, the display-device-side interface 423 may include a TV output interface 424, a digital output interface 425, an analog output interface 426, and a USB interface 427. The TV output interface 424 may be S-Video interface or composite video interface etc, the digital output interface 425 may be DVI etc, and the analog output interface 426 may be VGA interface etc. Those having ordinary skill in the art should choose the suitable display-device-side interface standard according to the requirement. In other words, the display-device-side interface 423 may include output interfaces of single pattern, or it can include output interfaces of various patterns to increase the convenience of usage. Accordingly, when a TV set 440 is to be used as the external display device of the portable computer 400, the TV set 440 and the TV output interface 424 can be connected through video cable. If a monitor 450 having a digital signal connector is to be used as the external display device of the portable computer 400, the monitor 450 and the digital output interface 425 can be connected through cable. If a display 460 ( for example, a CRT display) has only analog signal connector, then the display 460 and the analog output interface 426 can be connected through cable. If a display 470 has a USB connector, the display 470 and the USB interface 427 can be connected through a USB cable.

FIG. 4B illustrates the hot-pluggable video display card in FIG. 4A according to an embodiment of the present invention. The hot-pluggable video display card can be implemented referring to FIG. 4B. Here the hot-pluggable video display card 420 adopting the ExpressCard standard is used as an example. The display-device-side interface 423 of the hot-pluggable video display card 420 is disposed with a USB interface, an S-Video interface, a DVI interface, and a VGA interface etc. An external power supply 480 can be disposed accordingly to provide power required by the hot-pluggable video display card 420 if the power consumption of the high level video display card is to be considered.

Below, the portability of the portable computer will be considered. If the portable computer in the embodiment described above uses an external hot-pluggable video display card 420 for performing 3D or higher level video processing, the TV set 440, the display 450, or the display 460 has to be used to display the output result of the hot-pluggable video display card 420. In other words, the user has to carry an additional display device besides the portable computer and the hot-pluggable video display card 420. Thus, in the present embodiment, the embedded display device in the portable computer can be used as the additional display under such circumstance that using additional display device is not convenient. That is, the USB interface of the hot-pluggable video display card 420 is electrically connected to the USB interface of the portable computer so that the embedded display device of the portable computer can display the video processing result output by the hot-pluggable video display card 420 through USB interface.

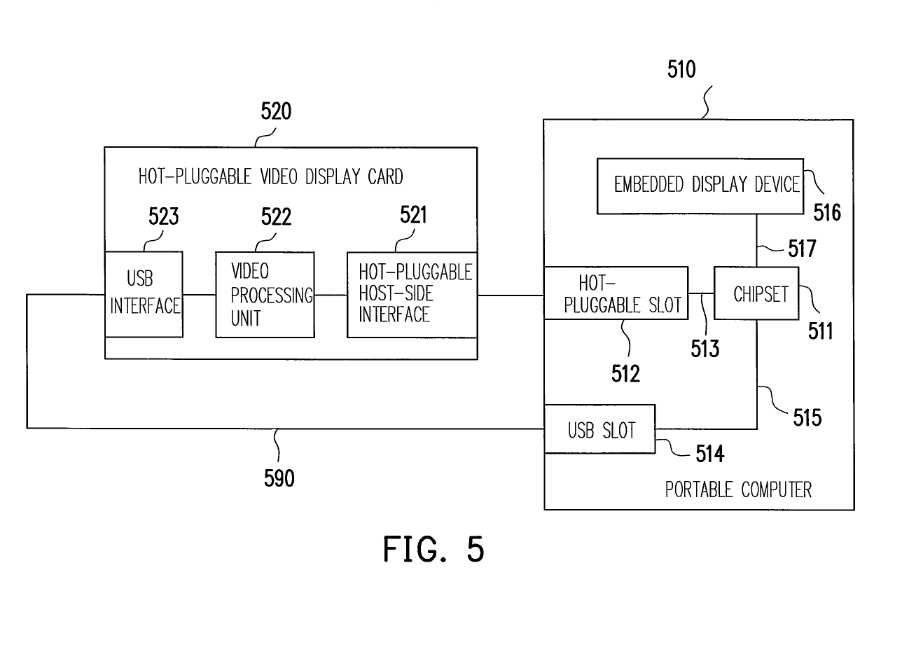

FIG. 5 illustrates the implementation of a hot-pluggable video display card according to an embodiment of the present invention. The hot-pluggable host-side interface 521, the video processing unit 522, and the display-device-side interface 523 of the hot-pluggable video display card 520 are the same to the hot-pluggable host-side interface 121, the video processing unit 122, and the display-device-side interface 123 of the hot-pluggable video display card 120 in FIG. 1, therefore the details will not be described herein. The hot-pluggable video display card 520 can also be implemented referring to the hot-pluggable video display card 420 in FIG. 4B. For the convenience of description of the present embodiment, only a USB interface 523 is illustrated as the display-device-side interface of the hot-pluggable video display card 520. However, the implementation of the display-device-side interface of the hot-pluggable video display card 520 is not limited to a USB interface.

In FIG. 5, the portable computer 510 includes a chipset 511, a hot-pluggable slot 512, a USB slot 514, and an embedded display device 516. The embedded display device 516 is usually an LCD display. The chipset 511 may be a single IC or the combination of multiple ICs. In the present embodiment, the chipset 511 has basic video processing function but which cannot be applied to high level video processing (for example, 3D video processing). The chipset 511 transmits the video data which has been simply processed to the embedded display device 516 through the bus 517, and the embedded display device 516 displays the video according to the output of the chipset 511.

When the user wants to use the portable computer 510 for high level video processing (for example, playing a 3D game), obviously, the basic video processing function built in the chipset 511 cannot meet the requirement. Here, the user can plug the hot-pluggable video display card 520 into the hot-pluggable slot 512 of the portable computer 510 and connect the USB interface 523 and the USB slot 514 with a USB cable 590. By electrically connecting the hot-pluggable host-side interface 521 and the hot-pluggable slot 512, the hot-pluggable slot 512 can transmit the unprocessed video data to the video processing unit 522 through the PCI Express bus 513, the hot-pluggable slot 512, and the hot-pluggable host-side interface 521. The video processing unit 522 can carry out high level video processing (for example, 3D video processing) to the video data received and output the video processing result. The video processing result can be transmitted to the chipset 511 through the USB interface 523, the USB cable 590, the USB slot 514, and the USB bus 515. Since video processing has been done to the video processing result, the chipset 511 does not need to perform additional video processing procedure, instead, the chipset 511 can directly provide the video processing result output by the hot-pluggable video display card 520 to the embedded display device 516. Then, the embedded display device 516 displays the video based on the video processing result output by the hot-pluggable video display card 520.

In overview, in the present invention, the hot-pluggable video display card is connected to the host unit through the hot-pluggable host-side interface, thus, the hot-pluggable video display card can be plugged to or unplugged from the computer system anytime without turning off the system. That is, the video processing performance of the computer system can be improved anytime in the present invention without affecting the operation of the system. In particular, the hot-pluggable video display card of the present invention can be directly connected to a notebook computer without turning off the notebook computer, and further the processing performance of the notebook computer to high level video (for example, 3D video) can be improved. Accordingly, the notebook computer can have more satisfying performance when the user needs to process 3D video and play 3D game. Moreover, the present invention can be applied to various video output interfaces such as computer monitor or TV set, so as to accomplish large screen effect. As described in an embodiment above, the video is transmitted back to the portable computer through the USB interface and displayed on the embedded display device of the portable computer through a software under such circumstance wherein using an additional display device is not convenient.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A hot-pluggable video display card for processing the video data of a host unit and transmitting the processing result to a display device, the hot-pluggable video display card comprising:
a hot-pluggable host-side interface, providing a connection interface between the hot-pluggable video display card and the host unit, and the hot-pluggable host-side interface providing hot plug-n-play function;
a video processing unit, coupled to the hot-pluggable host-side interface, receiving the video data output by the host unit and carrying out video processing; and
a display-device-side interface, coupled to the video processing unit, providing a connection interface between the hot-pluggable video display card and the display device for the hot-pluggable video display card so as to transmit the video processing result of the video processing unit to the display device.

2. The hot-pluggable video display card as claimed in claim 1, wherein the hot-pluggable host-side interface is up to the ExpressCard standard specified by Personal Computer Memory Card International Association (PCMCIA).

3. The hot-pluggable video display card as claimed in claim 1, wherein the video processing carried out by the video processing unit comprises 3D video processing.

4. The hot-pluggable video display card as claimed in claim 1, wherein the display-device-side interface comprises digital visual interface (DVI).

5. The hot-pluggable video display card as claimed in claim 1, wherein the display-device-side interface comprises video graphics array (VGA) interface.

6. The hot-pluggable video display card as claimed in claim 1, wherein the display-device-side interface comprises separate video (S-Video) interface.

7. The hot-pluggable video display card as claimed in claim 1, wherein the display-device-side interface comprises composite video interface.

8. The hot-pluggable video display card as claimed in claim 1, wherein the display-device-side interface comprises universal serial bus (USB) interface.

9. A computer system, comprising:
a host unit, comprising a hot-pluggable slot;
a hot-pluggable video display card, comprising:
a hot-pluggable host-side interface, coupled to the hot-pluggable slot, providing a connection interface between the hot-pluggable video display card and the host unit, and the hot-pluggable host-side interface providing hot plug-n-play function;
a video processing unit, coupled to the hot-pluggable host-side interface, receiving the video data output by the host unit and carrying out video processing; and
a display-device-side interface, coupled to the video processing unit; and
a display device, connected to the display-device-side interface of the hot-pluggable video display card.

10. The computer system as claimed in claim 9, wherein the hot-pluggable host-side interface is up to the ExpressCard standard specified by Personal Computer Memory Card International Association (PCMCIA).

11. The computer system as claimed in claim 9, wherein the video processing carried out by the video processing unit comprises 3D video processing.

12. The computer system as claimed in claim 9, wherein the display-device-side interface comprises digital visual interface (DVI).

13. The computer system as claimed in claim 9, wherein the display-device-side interface comprises video graphics array (VGA) interface.

14. The computer system as claimed in claim 9, wherein the display-device-side interface comprises separate video (S-Video) interface.

15. The computer system as claimed in claim 9, wherein the display-device-side interface comprises composite video interface.

16. The computer system as claimed in claim 9, wherein the display-device-side interface comprises universal serial bus (USB) interface.

17. The computer system as claimed in claim 9, wherein the host unit is a portable computer, and the display device is the display of the portable computer.

18. The computer system as claimed in claim 17, wherein the hot-pluggable video display card transmits the video data processed by the video processing unit to the portable computer through the display-device-side interface, and the video processing result output by the hot-pluggable video display card is displayed by the display device of the portable computer.
